(19) United States
(12) Patent Application Publication
(10) Pub. No.: US 2022/0404533 A1
(43) Pub. Date: Dec. 22, 2022

(54) QUANTUM DOT COLOR FILTER SUBSTRATE, METHOD FOR MANUFACTURING SAME, AND DISPLAY DEVICE

(71) Applicant: Shenzhen China Star Optoelectronics Semiconductor Display Technology Co., Ltd., Shenzhen, Guangdong (CN)

(72) Inventor: Miao ZHOU, Shenzhen, Guangdong (CN)

(21) Appl. No.: 17/440,795

(22) PCT Filed: Jul. 30, 2021
(86) PCT No.: PCT/CN2021/109540

§ 371 Date: Sep. 20, 2021

(30) Foreign Application Priority Data
Jun. 17, 2021 (CN) 202110671663.6

(51) Int. Cl. G02B 5/20; H01L 25/075

(52) U.S. Cl. CPC G02B 5/207; H01L 25/0753; G02B 5/201; H01L 33/483

(57) ABSTRACT

A quantum dot color filter substrate, a method for manufacturing the same, and a display device are provided. In the method for manufacturing the quantum dot color filter substrate, a plurality of red (R) color resist blocks, green (G) color resist blocks, and blue (B) color resist blocks each having a structure with a wide top surface and a narrow bottom surface are first formed, and then a quantum dot layer is formed on a silicon substrate, and then the quantum dot layer is contacted with the color resist layer, and then the silicon substrate is peeled off to transfer at least parts of the quantum dot layer in contact with the R color resist blocks and the G color resist blocks to surfaces of the R color resist blocks and the G color resist blocks.

### FIELD OF INVENTION

The present disclosure relates to the technical field of display, and particularly to a quantum dot color filter substrate, a method for manufacturing the same, and a display device.

### BACKGROUND

Whenever excited by light, quantum dots emit very pure color light. A color of light is determined by a constituent material, a size, and a shape of the quantum dots. Generally, the larger the particles, the longer the absorbed wavelength. And, the smaller the particles, the shorter the absorbed wavelength. Quantum dots with a size of 8 nm can absorb long-wavelength red and emit blue. Quantum dots with a size of 2 nm can absorb short-wavelength blue and emit red. Quantum dots can filter light, restore genuine colors of images, and increase a color gamut of a display screen. Therefore, quantum dot color filters have technical characteristics of wide color gamuts and wide viewing angles. The quantum dot color filters with a backlight technology can produce excellent picture quality, and is the most competitive product in a future display technology.

Currently, quantum dots and color resists are combined to form a quantum dot color filter layer. The display technology of the quantum dot color filter layer has not yet been mass-produced. In a current manufacturing technology, quantum dots are first prepared into a solution, the quantum dot solution is precisely sprayed on each color resist block by inkjet printing, and then the quantum dot solution is dried to form a plurality of quantum dot blocks. In this process, photoresist polymers of the color resist blocks are doped into the quantum dot solution, so that light extraction efficiency of the quantum dot blocks in a reliability test is reduced.

Accordingly, it is necessary to provide a quantum dot color filter substrate, a method for manufacturing the same, and a display device to solve the above technical problems that in the process of manufacturing the quantum dot blocks by inkjet printing, the quantum dot blocks formed by drying the quantum dot solution doped with the photoresist polymers of the color resist blocks have poor light extraction efficiency in the reliability test.

### SUMMARY OF DISCLOSURE

The present disclosure provides a quantum dot color filter substrate, a method for manufacturing the same, and a display device that can solve technical problems that in a current process of manufacturing quantum dot blocks by inkjet printing, the quantum dot blocks formed by drying a quantum dot solution doped with photoresist polymers of color resist blocks have poor light extraction efficiency in a reliability test.

In order to solve the above problems, the present disclosure provides the following technical solutions.

The present disclosure provides a method for manufacturing a quantum dot color filter substrate. The method comprises:

step S10: forming a color resist layer under a base substrate, wherein the color resist layer comprises a plurality of red (R) color resist blocks, green (G) color resist blocks, and blue (B) color resist blocks arranged in an array, each of the R color resister blocks, the G color resister blocks, and the B color resister blocks has a structure with a wide top surface and a narrow bottom surface, and the wide top surface contacts a bottom surface of the base substrate;

step S20: forming a quantum dot layer on a silicon substrate, wherein the quantum dot layer is a mixed layer comprising a plurality of red quantum dots and green quantum dots; and

step S30: heating the quantum dot layer and the color resist layer, contacting them, keeping them warm for a preset time, cooling them to room temperature, and peeling off the silicon substrate to transfer at least parts of the quantum dot layer in contact with the R color resist blocks and the G color resist blocks to surfaces of the R color resist blocks and the G color resist blocks, so that a plurality of quantum dot blocks are formed on the narrow top surfaces of the R color resist blocks and the G color resist blocks.

In an embodiment, the step S30 further comprises: transferring parts of the quantum dot layer in contact with the B color resist blocks to surfaces of the B color resist blocks.

In an embodiment, the step S20 further comprises: adding a plurality of high refractive index scattering particles into the B color resist blocks, and performing hydrophilic treatment on the surfaces of the B color resist blocks. The high refractive index scattering particles are one or more crystalline materials selected from a group consisting of titanium dioxide, zirconium oxide, barium titanate, and titanium dioxide. A mass fraction of the crystalline materials in the B color resist blocks is 0.3% to 8%.

In an embodiment, the step S20 further comprises: forming a barrier layer on a periphery of each of the quantum dot blocks. The barrier layer is made of silicon oxide, silicon nitride, or a combination thereof. The barrier layer has a thickness of 1 nm to 50 nm.

In an embodiment, forming a metal layer on parts of the barrier layer corresponding to the R color resist blocks and the G color resist blocks. The metal layer is made of nano silver, a composite material of nano silver and silicon dioxide, a composite material of nano silver and titanium dioxide, or any combination thereof. The metal layer has a thickness of 1 nm to 50 nm.

According to the method for manufacturing the quantum dot color filter substrate in the above embodiments, the present disclosure further provides a quantum dot color filter substrate. The quantum dot color filter substrate comprises:

a base substrate;

a color resist layer disposed under the base substrate and comprising a plurality of red (R) color resist blocks, green (G) color resist blocks, and blue (B) color resist blocks arranged in an array, wherein each of the R color resister blocks, the G color resister blocks, and the B color resister blocks has a structure with a wide top surface and a narrow bottom surface, and the wide top surface contacts a bottom surface of the base substrate; and

a quantum dot layer comprising a plurality of quantum dot blocks arranged in an array, wherein the quantum dot blocks are made of a mixed layer comprising a plurality of red quantum dots and green quantum dots, and the quantum dot blocks are disposed at least under the narrow bottom surfaces of the R color resist blocks and the G color resist blocks.

In an embodiment, a cross-sectional shape of the structure with the wide top surface and the narrow bottom surface is an inverted isosceles trapezoid.

In an embodiment, the quantum dot blocks are disposed under and in alignment with the B color resist blocks.

In an embodiment, the quantum dot color filter substrate further comprises a barrier layer disposed on a periphery of each of the quantum dot blocks and made of silicon oxide, silicon nitride, or a combination thereof.

In an embodiment, the quantum dot color filter substrate further comprises a metal layer disposed on parts of the barrier layer corresponding to the R color resist blocks and the G color resist blocks and comprising silver.

In an embodiment, the quantum dot blocks are not disposed under the B color resist blocks, and the B color resist blocks are added with a plurality of high refractive index scattering particles.

In an embodiment, the quantum dot color filter substrate further comprises a barrier layer disposed on a periphery of each of the quantum dot blocks and made of silicon oxide, silicon nitride, or a combination thereof.

In an embodiment, the quantum dot color filter substrate further comprises a metal layer disposed on parts of the barrier layer corresponding to the R color resist blocks and the G color resist blocks and comprising silver.

In an embodiment, the high refractive index scattering particles are made of one or more of titanium dioxide, zirconium oxide, and barium titanate. A mass fraction of the high refractive index scattering particles in the B color resist blocks is 0.3% to 8%.

In an embodiment, the green quantum dots are made of one or more of ZnCdSe₂, InP, and Cd₂SSe, and the red quantum dots are made of one or more of CdSe, Cd₂SeTe, and InAs.

In an embodiment, an inclination angle between two waists of the inverted isosceles trapezoid and a horizontal line is 15° to 45°.

According to the quantum dot color filter substrate in the above embodiments, the present disclosure further provides a display device. The display device comprises the quantum dot color filter substrate in the above embodiments and a micro-light emitting diode (micro-LED) backlight. The quantum dot color filter substrate is disposed on a light-emitting side of the micro-LED backlight.

In an embodiment, the micro-LED backlight comprises: a driving circuit board; a plurality of miniature red light-emitting devices, miniature green light-emitting devices, and miniature blue light-emitting devices disposed on the driving circuit board; and a plurality of isolation walls disposed between every two adjacent miniature light-emitting devices.

In an embodiment, the quantum dot color filter substrate comprises the R color resister blocks, the G color resister blocks, and the B color resister blocks arranged in the array. The miniature red light-emitting devices, the miniature green light-emitting devices, and the miniature blue light-emitting devices are disposed in alignment with the R color resister blocks, the G color resister blocks, and the B color resister blocks, respectively.

In an embodiment, the quantum dot blocks are disposed under and in alignment with the B color resist blocks. Alternatively, the quantum dot blocks are not disposed under the B color resist blocks, and the B color resist blocks are added with a plurality of high refractive index scattering particles. The high refractive index scattering particles are made of one or more of titanium dioxide, zirconium oxide, and barium titanate. A mass fraction of the high refractive index scattering particles in the B color resist blocks is 0.3% to 8%.

The present disclosure provides a quantum dot color filter substrate, a method for manufacturing the same, and a display device. In the method for manufacturing the quantum dot color filter substrate, a plurality of red (R) color resist blocks, green (G) color resist blocks, and blue (B) color resist blocks each having a structure with a wide top surface and a narrow bottom surface are first formed, and then a quantum dot layer is formed on a silicon substrate, and then the quantum dot layer is contacted with the color resist layer, and then the silicon substrate is peeled off to transfer at least parts of the quantum dot layer in contact with the R color resist blocks and the G color resist blocks to surfaces of the R color resist blocks and the G color resist blocks, so that a plurality of quantum dot blocks are formed on the narrow top surfaces of the R color resist blocks and the G color resist blocks. The method avoids a situation that photoresist polymers in an inkjet printing technology are doped into a quantum dot solution. That is, the method prevents the photoresist technology in a current manufacturing technology from having a greater impact on light efficiency and reliability of quantum dots. Therefore, the quantum dot blocks formed by transfer printing in the present disclosure have higher light extraction efficiency and higher utilization rate of the quantum dots.

### BRIEF DESCRIPTION OF DRAWINGS

In order to more clearly illustrate technical solutions in embodiments and the prior art, a brief description of accompanying drawings used in a description of the embodiments and the prior art will be given below. Obviously, the accompanying drawings in the following description are merely some embodiments of the present disclosure. For those skilled in the art, other drawings may be obtained from these accompanying drawings without creative labor.

FIG. 1 is a schematic structural diagram of a combination of a quantum dot block and a color resist block according to an embodiment of the present disclosure.

FIG. 2 is a schematic structural diagram of a quantum dot color resist of the present disclosure and a quantum dot color resist in the prior art.

FIG. 3 to FIG. 5 are schematic structural diagrams respectively showing first to third types of quantum dot color filter substrates according to an embodiment of the present disclosure.

FIG. 6 to FIG. 8 are schematic structural diagrams respectively showing first to third types of display devices according to an embodiment of the present disclosure.

FIG. 9 is a schematic flowchart of a method for manufacturing a display device according to an embodiment of the present disclosure.

FIG. 10 to FIG. 12 are schematic structural diagrams respectively showing fourth to sixth types of quantum dot color filter substrates according to an embodiment of the present disclosure.

FIG. 13 to FIG. 15 are schematic structural diagrams respectively showing fourth to sixth types of display devices according to an embodiment of the present disclosure.

FIG. 16 is the other schematic flowchart of a method for manufacturing a display device according to an embodiment of the present disclosure.

FIG. 17 is a schematic diagram of a structure and an arrangement of the color resist blocks according to an embodiment of the present disclosure.

FIG. 18 to FIG. 20 are schematic diagrams of structures and arrangements of quantum dot blocks aligned with the color resist blocks according to an embodiment of the present disclosure.

### DETAILED DESCRIPTION

The following description of various embodiments with reference to accompanying drawings is used to illustrate specific embodiments of the present disclosure that can be practiced. Directional terms mentioned in the present disclosure, such as “above”, “below”, “front”, “rear”, “left”, “right”, “inside”, “outside”, and “beside”, are merely used to indicate directions of the accompanying drawings. Therefore, the directional terms are used for illustrating and understanding the present disclosure rather than limiting the present disclosure. In the drawings, elements with similar structures are indicated by same reference numerals.

The present disclosure provides the following embodiments that can solve technical problems that in a current process of manufacturing quantum dot blocks by inkjet printing, the quantum dot blocks formed by drying a quantum dot solution doped with photoresist polymers of color resist blocks have poor light extraction efficiency in a reliability test.

In order to solve the above technical problems, the present disclosure provides a method for manufacturing a quantum dot color filter substrate. The method comprises:

step S10: forming a color resist layer under a base substrate, wherein the color resist layer comprises a plurality of red (R) color resist blocks, green (G) color resist blocks, and blue (B) color resist blocks arranged in an array, each of the R color resister blocks, the G color resister blocks, and the B color resister blocks has a structure with a wide top surface and a narrow bottom surface, and the wide top surface contacts a bottom surface of the base substrate;

step S20: forming a quantum dot layer on a silicon substrate, wherein the quantum dot layer is a mixed layer comprising a plurality of red quantum dots and green quantum dots; and

step S30: heating the quantum dot layer and the color resist layer, contacting them, keeping them warm for a preset time, cooling them to room temperature, and peeling off the silicon substrate to transfer at least parts of the quantum dot layer in contact with the R color resist blocks and the G color resist blocks to surfaces of the R color resist blocks and the G color resist blocks, so that a plurality of quantum dot blocks are formed on the narrow top surfaces of the R color resist blocks and the G color resist blocks.

Preferably, the step S30 further comprises: transferring parts of the quantum dot layer in contact with the B color resist blocks to surfaces of the B color resist blocks. The step S30 further comprises: forming a barrier layer on a periphery of each of the quantum dot blocks. The barrier layer is made of silicon oxide, silicon nitride, or a combination thereof. The barrier layer has a thickness of 1 nm to 50 nm. The step S30 further comprises: forming a metal layer on parts of the barrier layer corresponding to the R color resist blocks and the G color resist blocks. The metal layer is made of nano silver, a composite material of nano silver and silicon dioxide, a composite material of nano silver and titanium dioxide, or any combination thereof. The metal layer has a thickness of 1 nm to 50 nm.

Preferably, the step S20 further specifically comprises: adding a plurality of high refractive index scattering particles into the B color resist blocks, and performing hydrophilic treatment on the surfaces of the B color resist blocks. The high refractive index scattering particles are one or more crystalline materials selected from a group consisting of titanium dioxide, zirconium oxide, barium titanate, and titanium dioxide. A mass fraction of the crystalline materials in the B color resist blocks is 0.3% to 8%. The step S20 further comprises: forming a barrier layer on a periphery of each of the quantum dot blocks. The barrier layer is made of silicon oxide, silicon nitride, or a combination thereof. The barrier layer has a thickness of 1 nm to 50 nm. The step S20 further comprises: forming a metal layer on parts of the barrier layer corresponding to the R color resist blocks and the G color resist blocks. The metal layer is made of nano silver, a composite material of nano silver and silicon dioxide, a composite material of nano silver and titanium dioxide, or any combination thereof. The metal layer has a thickness of 1 nm to 50 nm.

In a method for manufacturing a quantum dot color filter substrate of the present disclosure, a plurality of red (R) color resist blocks, green (G) color resist blocks, and blue (B) color resist blocks each having a structure with a wide top surface and a narrow bottom surface are first formed, and then a quantum dot layer is formed on a silicon substrate, and then the quantum dot layer is contacted with the color resist layer, and then the silicon substrate is peeled off to transfer at least parts of the quantum dot layer in contact with the R color resist blocks and the G color resist blocks to surfaces of the R color resist blocks and the G color resist blocks, so that a plurality of quantum dot blocks are formed on the narrow top surfaces of the R color resist blocks and the G color resist blocks. The method avoids a situation that photoresist polymers in an inkjet printing technology are doped into a quantum dot solution. That is, the method prevents the photoresist technology in a current manufacturing technology from having a greater impact on light efficiency and reliability of quantum dots. Therefore, the quantum dot blocks formed by transfer printing in the present disclosure have higher light extraction efficiency and higher utilization rate of the quantum dots.

The quantum dot color filter substrate is manufactured by the method for manufacturing the quantum dot color filter substrate in the above embodiments. The quantum dot color filter substrate comprises a base substrate, a color resist layer disposed under the base substrate, and a quantum dot layer disposed under the color resist layer. The color resist layer comprises a plurality of red (R) color resist blocks, green (G) color resist blocks, and blue (B) color resist blocks each having a structure with a wide top surface and a narrow bottom surface. The quantum dot layer comprises a plurality of quantum dot blocks arranged in an array. The quantum dot blocks are made of a mixed layer comprising a plurality of red quantum dots and green quantum dots. The quantum dot blocks are disposed at least under the narrow bottom surfaces of the R color resist blocks and the G color resist blocks. Because the quantum dot blocks of the present disclosure are made of the mixed layer comprising the red quantum dots and the green quantum dots, and the quantum dot blocks disposed on the R color resist blocks and the G color resist blocks have a same structure, precise alignment is not required. This avoids a need for the inkjet printing technology to precisely align each of the color resist blocks. Therefore, compared to an inkjet printing method, this transfer method of the present disclosure is not limited by large-size and high-resolution display panels, and can manufacture quantum dot blocks with higher precision, and can meet requirements of high resolution. Furthermore, the R color resist blocks, G color resist blocks, and B color resist blocks each having the structure with the wide top surface and the narrow bottom surface in the present disclosure can significantly reduce light crosstalk between adjacent color resist blocks and improve light-emitting quality of the quantum dot color filter substrate.

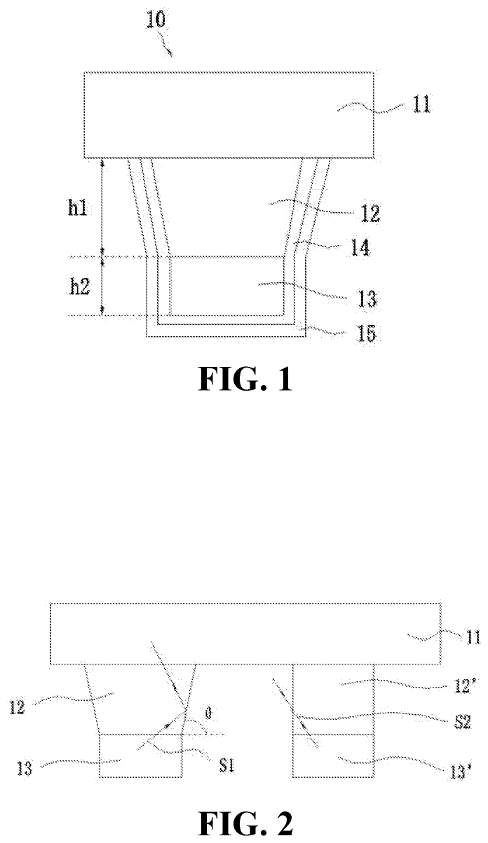

Specifically, as shown in FIG. 1, the present disclosure provides a stacking module 10 of a quantum dot block and a color resist block. The stacking module 10 comprises a base substrate 11, the color resist block 12, the quantum dot block 13, a barrier layer 14, and a metal layer 15. The color resist block 12 and the quantum dot block 13 are sequentially disposed under the base substrate 11. The barrier layer 14 and the metal layer 15 are sequentially disposed on a periphery of the color resist block 12 and the quantum dot block 13. The color resist block 12 has a structure with a wide top surface and a narrow bottom surface, and is preferably an inverted isosceles trapezoid. The quantum dot block 13 is disposed on the narrow top surface. An inclination angle between two waists of the inverted isosceles trapezoid and a horizontal line is 15° to 45°. A color resist block design (trapezoidal design) with a reduced inclination angle can significantly reduce crosstalk between pixels of a quantum dot color filter substrate. The color resist block 12 has a height h1 of 1 um to 5 um. The quantum dot block 13 has a height h2 of 1 um to 10 um. The barrier layer 14 has a thickness of 1 nm to 50 nm. The metal layer 15 has a thickness of 1 nm to 50 nm. The color resist block 12 is made of a R/G/B color resist of SPR 220-4.5. The quantum dot block 13 is a mixed layer comprising a plurality of red quantum dots and green quantum dots. The green quantum dots are made of one or more of ZnCdSe₂, InP, and Cd₂SSe. The red quantum dots are made of one or more of CdSe, Cd₂SeTe, and InAs. The barrier layer 14 is made of silicon oxide, silicon nitride, or a combination thereof. The metal layer 15 comprises silver. A nano silver (Ag) layer is configured as a surface plasmon resonance layer to improve a brightness of light. The characteristic absorption peak of the metal layer 15 is preferably 430 nm to 500 nm.

In order to illustrate that a shape of the color resist block 12 of the present disclosure is better than a shape of a color resist block 12′ in the prior art, as shown in FIG. 2, the two color resist blocks are formed on the same base substrate 11, and a same light is emitted to the quantum dot block 13 and a quantum dot block 13′. A surface of the color resist block 12 of the present disclosure is provided with a metal layer. The metal layer comprises silver and is configured as a reflective layer. Furthermore, the color resist block 12 has the structure with the wide top surface and the narrow bottom surface, and has an inclined plane. When the light is incident on the inclined plane, a normal line is perpendicular to the inclined plane. Compared with a normal line perpendicular to a vertical plane, this increases an angle of incidence, so that reflections easily occur. A light S1 is emitted to the inclined plane of a side edge of the color resist block 12 and the metal layer 15 surrounding it, and finally exits from a side of the color resist block 12 where the base substrate 11 is attached. This avoids color mixing between adjacent color resist blocks. A light S2 emitted from the quantum dot block 13′ of the prior art is not reflected on a surface of the color resist block 12, and is directly emitted to an adjacent color resist block. This causes color mixing between adjacent color resist blocks, resulting in color differences in a display panel. It can be understood that in the present disclosure, by changing the shape of the color resist block 12, a light filtering performance of the color resist block 12 can be improved.

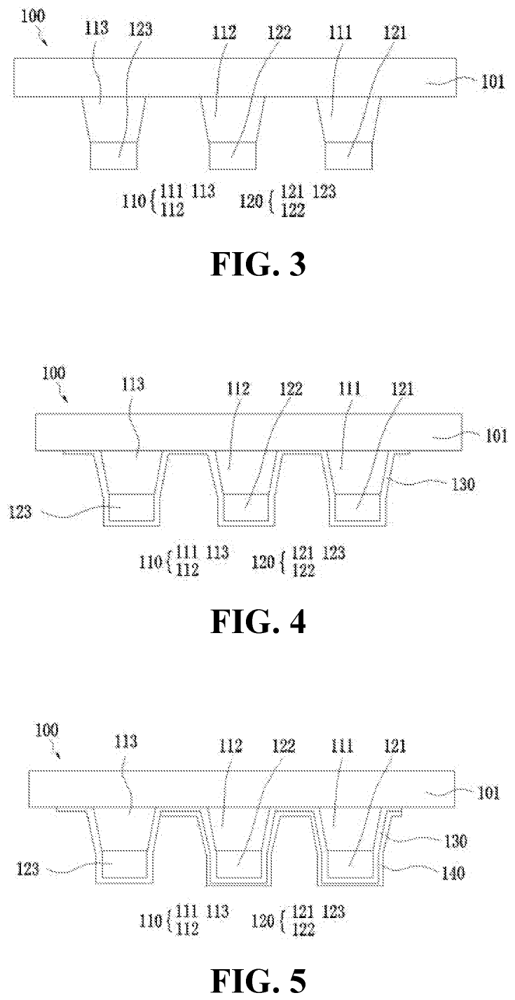

The present disclosure improves current quantum dot color filter substrates, thereby obtaining six types of quantum dot color filter substrates with excellent performance and six corresponding display devices, as shown in FIG. 3 to FIG. 16. According to whether a B color resist block 113 is provided with a quantum dot block, the present disclosure uses two specific embodiments to illustrate specific structures of quantum dot plus color resist.

FIG. 3 to FIG. 9 are accompanying drawings of a first embodiment, and the first embodiment is described below.

Please refer to FIG. 3, which is a schematic structural diagram of a first type of quantum dot color filter substrate 100 according to an embodiment of the present disclosure. The quantum dot color filter substrate 100 comprises a base substrate 101, a color resist layer 110 disposed under the base substrate 101, and a quantum dot layer 120 disposed under the color resist layer 110. The color resist layer 110 comprises a plurality of red (R) color resist blocks 111, green (G) color resist blocks 112, and blue (B) color resist blocks 113 arranged in an array. The quantum dot layer 120 comprises a plurality of quantum dot blocks arranged in an array, such as quantum dot blocks 121, quantum dot blocks 122, and quantum dot blocks 123. The quantum dot blocks 121, the quantum dot blocks 122, and the quantum dot blocks 123 are all mixed layers comprising red quantum dots and green quantum dots. The green quantum dots are made of one or more of ZnCdSe₂, InP, and Cd₂SSe. The red quantum dots are made of one or more of CdSe, Cd₂SeTe, and InAs. The R color resist blocks 111, the G color resist blocks 112, and the blue B color resist blocks 113 are made of R, G, and B color resists of SPR 220-4.5, respectively.

The quantum dot blocks are transferred to corresponding color resist blocks. The quantum dot blocks 121, the quantum dot blocks 122, and the quantum dot blocks 123 are disposed in alignment with the R color resist blocks 111, the G color resist block 112, and the B color resist blocks 113, respectively. After a transfer printing process, an incident light is filtered by the quantum dot blocks, only red light can penetrate the R color resist blocks 111, only green light can penetrate the G color resist blocks 112, and only blue light can penetrate the B color resist blocks 113. During the transfer printing process, there is no need to specifically align the color resist blocks with a specific color, so the transfer printing process is easier than that of monochromatic quantum dot layers. Because the R color resist blocks 111, the G color resist blocks 112, and the B color resist blocks 113 are all provided with the quantum dot blocks, the incident light will have a same effect after being filtered by the same quantum dot blocks. This avoids a color gamut difference between R, G, and B lights, thereby improving quality of light emitted by the quantum dot color filter substrate.

Please refer to FIG. 4, which is a schematic structural diagram of a second type of quantum dot color filter substrate 100 according to an embodiment of the present disclosure. A surface of the quantum dot color filter substrate 100 of this embodiment is provided with a barrier layer 130. The barrier layer 130 is made of silicon oxide, silicon nitride, or a combination thereof, and is configured to prevent water and oxygen from invading the quantum dot layer 120 and the color resist layer 110. The other structure is similar to that of FIG. 3, and is not described in detail herein.

Please refer to FIG. 5, which is a schematic structural diagram of a third type of quantum dot color filter substrate 100 according to an embodiment of the present disclosure. Parts of the barrier layer 130 corresponding to the R color resist blocks 111 and the G color resist blocks 112 are provided with a metal layer 140. The metal layer 140 comprises silver. A nano silver (Ag) layer is configured as a surface plasmon resonance layer to improve a brightness of light. In addition, the metal layer 140 is not disposed on the B color resist blocks 113, thereby increasing a transmittance of the B color resist blocks 113. The other structure is similar to that of FIG. 4, and is not described in detail herein.

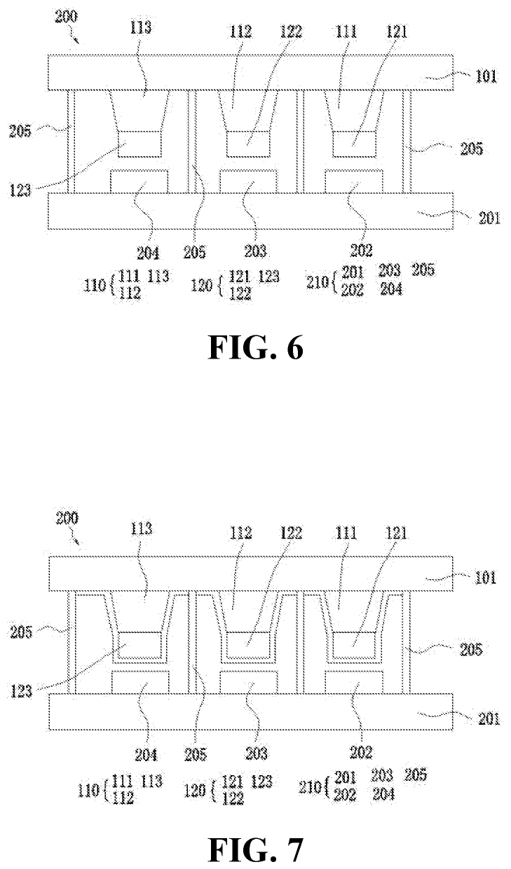

According to the above three types of quantum dot color filter substrates 100, the present disclosure provides three types of corresponding display devices as shown in FIG. 6 to FIG. 8.

Please refer to FIG. 6, which is a schematic structural diagram of a first type of a display device according to an embodiment of the present disclosure. The display device 200 comprises a quantum dot color filter substrate as shown in FIG. 3 and a micro-light emitting diode (micro-LED) backlight 210. The quantum dot color filter substrate is disposed on a light-emitting side of the micro-LED backlight 210. The micro-LED backlight 210 comprises a driving circuit board 201; a plurality of miniature red light-emitting devices 202, miniature green light-emitting devices 203, and miniature blue light-emitting devices 204 disposed on the driving circuit board; and a plurality of isolation walls 205 disposed between every two adjacent miniature light-emitting devices. The miniature red light-emitting devices 202, the miniature green light-emitting devices 203, and the miniature blue light-emitting devices 204 are disposed in alignment with the R color resister blocks 111, the G color resister blocks 112, and the B color resister blocks 113, respectively. The isolation walls 205 are mainly configured for connection and support. A structure of the quantum dot color filter substrate is same as that of FIG. 3, wherein the quantum dot blocks 123 are disposed under and in alignment with the B color resist blocks 113, which is not described in detail herein.

Please refer to FIG. 7, which is a schematic structural diagram of a second type of a display device according to an embodiment of the present disclosure. The display device 200 comprises a quantum dot color filter substrate as shown in FIG. 4 and a micro-LED backlight 210. The micro-LED backlight 210 is similar to that in FIG. 6, and a structure of the quantum dot color filter substrate is same as that of FIG. 4, and their specific structures are not described in detail herein.

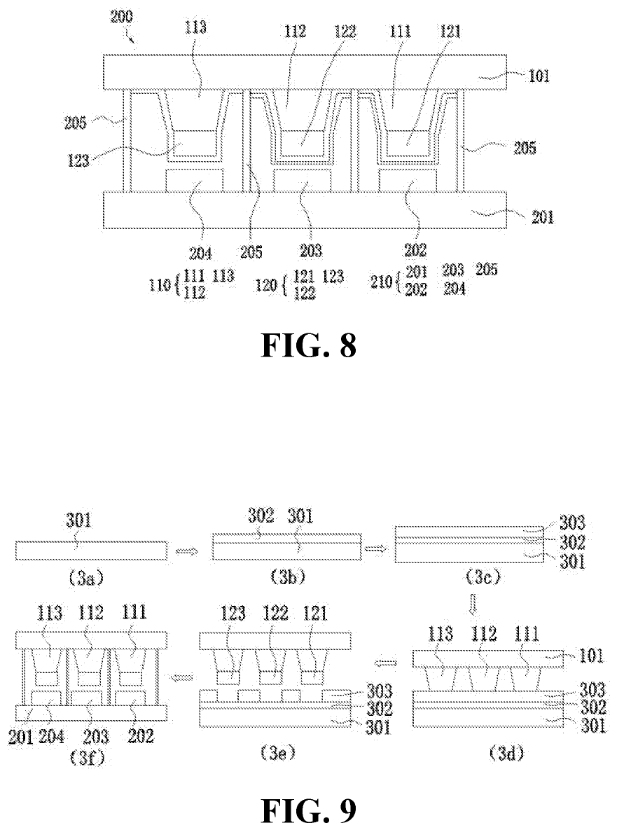

Please refer to FIG. 8, which is a schematic structural diagram of a third type of a display device according to an embodiment of the present disclosure. The display device 200 comprises a quantum dot color filter substrate as shown in FIG. 5 and a micro-LED backlight 210. The micro-LED backlight 210 is similar to that in FIG. 6, and a structure of the quantum dot color filter substrate is same as that of FIG. 5, and their specific structures are not described in detail herein.

According to the above three types of quantum dot color filter substrates 100 and the corresponding three types of display devices, the present disclosure provides a method for manufacturing a display device. The method comprises the following steps.

Step S10: providing a base substrate, and forming a plurality of red (R) color resist blocks, green (G) color resist blocks, and blue (B) color resist blocks each having a structure with a wide top surface and a narrow bottom surface under the base substrate.

Step S20: providing a silicon substrate, forming a quantum dot layer on the silicon substrate, transferring parts of the quantum dot layer in contact with the R color resist blocks, the G color resist blocks, and B color resist blocks to surfaces of the R color resist blocks, the G color resist blocks, and B color resist blocks, and peeling off the silicon substrate to complete manufacture of a quantum dot color filter substrate. The quantum dot block is a mixed layer comprising a plurality of red quantum dots and green quantum dots.

Step S30: disposing the quantum dot color filter substrate in alignment with a corresponding micro-LED backlight to obtain the R/G/B display device.

Preferably, the step S20 further comprises: forming a barrier layer on a periphery of the quantum dot color filter substrate. The barrier layer is made of silicon oxide, silicon nitride, or a combination thereof. The barrier layer has a thickness of 1 nm to 50 nm. The step S20 further comprises: forming a metal layer on parts of the barrier layer and the quantum dot layer corresponding to the R and G color resist blocks. The metal layer is made of nano silver, a composite material of nano silver and silicon dioxide, a composite material of nano silver and titanium dioxide, or any combination thereof. The metal layer has a thickness of 1 nm to 50 nm.

Please refer to FIG. 9, which is a schematic flowchart of a method for manufacturing a display device according to an embodiment of the present disclosure. As shown in (3a) to (3c) in FIG. 9, a S1 substrate 301 is provided. After a surface of the S1 substrate 301 is cleaned, ODTS is coated on the surface of the S1 substrate to form an ODETS layer 302. ODETS is octadecyl trichlorosilane and its derivatives. A plurality of red and green quantum dots dispersed in a n-hexane solution are spin-coated on the ODETS layer 302 to form a quantum dot layer 303 with a thickness of Sum to 20 um.

As shown in (3d) and (3e) in FIG. 9, a flexible photoresist (such as poly(dimethylsiloxane), PDMS) substrate 101 is patterned by a yellow light process to form a R/G/B photoresist layer. The photoresist layer is in contact with the quantum dot layer 303. Parts of the quantum dot layer 303 in contact with the R and G color resist blocks are transferred to surfaces of the R and G color resist blocks, heated at 50 to 100° C. for 10 min to 60 min, and then cooled to room temperature. The flexible substrate PDMS is quickly peeled from the silicon (Si) substrate to complete manufacture of a quantum dot color filter substrate. Peeling forces of the following three layers: the ODETS layer 302<the PR-PDMS substrate<the quantum dot layer 303. In these steps, a photoresist color resist technology has high precision and meets high-resolution requirements. A transfer printing process of quantum dots is not affected by the yellow light process and can maintain high efficiency. Photoresists prevent ambient light from exciting quantum dots to emit light, thereby improving contrast. The other layers may be treated after the transfer printing process to improve reliability and light conversion efficiency. The B color resist blocks are treated with hydrophilic treatment, so the quantum dots will not be transferred to them, which improves a transmittance and a color gamut of blue light. These steps can be applied to flexible display products.

As shown in (3f) in FIG. 9, the quantum dot color filter substrate is disposed in alignment with a corresponding micro-LED backlight to obtain the R/G/B display device of FIG. 6. The micro-LED backlight comprises a driving circuit board 201; a plurality of miniature red light-emitting devices 202, miniature green light-emitting devices 203, and miniature blue light-emitting devices 204 disposed on the driving circuit board; and a plurality of isolation walls disposed between every two adjacent miniature light-emitting devices. The isolation walls are mainly configured for connection and support. The quantum dot color filter substrate comprises the R color resister blocks, the G color resister blocks, and the B color resister blocks arranged in the array. The miniature red light-emitting devices, the miniature green light-emitting devices, and the miniature blue light-emitting devices are disposed in alignment with the R color resister blocks, the G color resister blocks, and the B color resister blocks, respectively. The quantum dot blocks are disposed under and in alignment with the B color resist blocks. Alternatively, the quantum dot blocks are not disposed under the B color resist blocks, and the B color resist blocks are added with a plurality of high refractive index scattering particles. The high refractive index scattering particles are made of one or more of titanium dioxide, zirconium oxide, and barium titanate. A mass fraction of the high refractive index scattering particles in the B color resist blocks is 0.3% to 8%.

Please note that structures of the other display devices are similar to that of FIG. 6. The barrier layer and the metal layer are generally formed by evaporation or coating. After the transfer printing process is completed, a silicon oxide layer or a silicon nitride layer with a thickness of 1 nm to 50 nm is vapor-deposited on a surface of the quantum dot layer at a low temperature to form the barrier layer to block water and oxygen. An Ag metal layer with a thickness of 1-50 nm is sputtered on an outside at room temperature to form the metal layer. In order to improve a light conversion efficiency of the quantum dots, after the metal layer is sputtered, parts of the metal layer on surfaces of the B color resist blocks may be selectively etched to increase a transmittance of the B color resist blocks.

In FIG. 3 to FIG. 9, the quantum dot blocks are transfer printed to the R color resist blocks 111, the G color resist blocks 112 and the B color resist blocks 113. The transfer printing process of the present disclosure avoids a situation that photoresist polymers in the inkjet printing technology are doped into a quantum dot solution. That is, the transfer printing process prevents the photoresist technology in a current manufacturing technology from having a greater impact on light efficiency and reliability of the quantum dots. In addition, the quantum dot blocks are made of the mixed layer comprising the red and green quantum dots. After the R color resist blocks 111 are transfer printed with the quantum dot blocks, only red light passes through them. After the G color resist blocks 112 are transfer printed with the quantum dot blocks, only green light passes through them. After the B color resist blocks 113 are transfer printed with the quantum dot blocks, only blue light passes through them. This can effectively improve a difference in exit angle of the R, G, and B color lights, thereby preventing yellowish images from being displayed at a large viewing angle, and improving a display quality of a display panel.

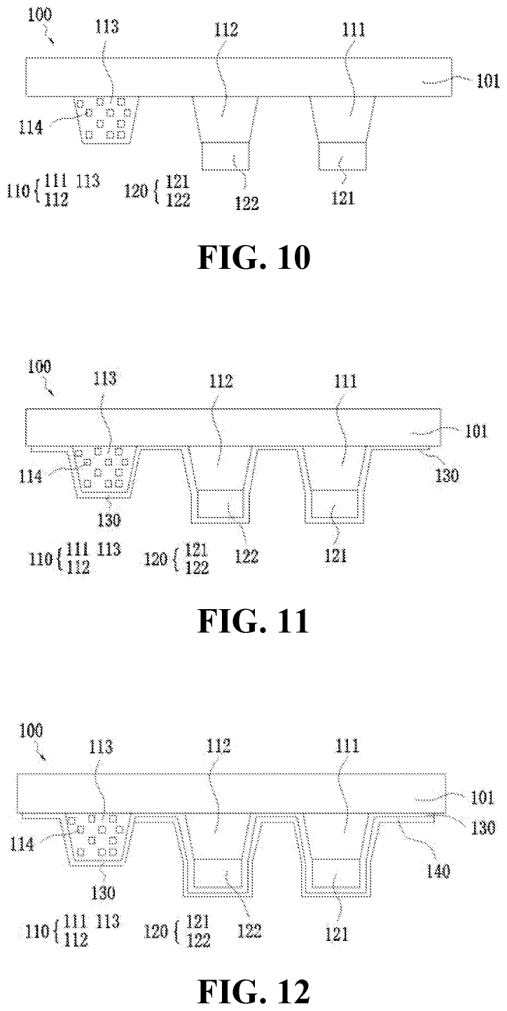

FIG. 10 to FIG. 16 are accompanying drawings of a second embodiment, and the second embodiment is described below.

Please refer to FIG. 10, which is a schematic structural diagram of a fourth type of quantum dot color filter substrate 100 according to an embodiment of the present disclosure. The quantum dot color filter substrate 100 comprises a base substrate 101, a color resist layer 110, and a quantum dot layer 120. The color resist layer 110 is disposed under the base substrate 101, and comprises a plurality of red (R) color resist blocks 111, green (G) color resist blocks 112, and blue (B) color resist blocks 113 arranged in an array. The B color resist blocks 113 are added with a plurality of high refractive index scattering particles 114. The high refractive index scattering particles 114 are made of one or more of titanium dioxide, zirconium oxide, and barium titanate. The quantum dot layer 120 comprises a plurality of quantum dot blocks arranged in an array, such as quantum dot blocks 121 and quantum dot blocks 122. The quantum dot blocks 121 and the quantum dot blocks 122 are disposed in alignment with the R color resister blocks 111 and the G color resister blocks 112, respectively. The quantum dot blocks are not disposed under the B color resist blocks 113. The B color resist blocks 113 are added with the high refractive index scattering particles. The high refractive index scattering particles are made of one or more of titanium dioxide, zirconium oxide, and barium titanate. A mass fraction of the high refractive index scattering particles in the B color resist blocks is 0.3% to 8%. A cross-sectional shape of each of the R color resist blocks 111, the G color resist blocks 112, and the B color resist blocks 113 is a structure with a wide top surface and a narrow bottom surface. The wide bottom surface is attached to a bottom surface of the base substrate 101. The narrow top surface is attached to a surface of one corresponding quantum block 102. The structure with the wide top surface and the narrow bottom surface is preferably an inverted isosceles trapezoid. The quantum dot blocks 121 and the quantum dot blocks 122 are mixed layers comprising red quantum dots and green quantum dots. The quantum dot layer is transferred to corresponding color resist blocks. When the R color resist blocks 111 are combined with the quantum dot blocks 121, only red light passes through them. When the G color resist blocks 112 are combined with the quantum dot blocks 122, only green light passes through them. The green quantum dots are made of one or more of ZnCdSe₂, InP, and Cd₂SSe. The red quantum dots are made of one or more of CdSe, Cd₂SeTe, and InAs. The R color resist blocks 111, the G color resist blocks 112, and the blue B color resist blocks 113 are made of R, G, and B color resists of SPR 220-4.5, respectively.

In this embodiment, the quantum dot blocks are transfer printed to the R color resist blocks 111 and the G color resist blocks 112 to improve a utilization rate of the transfer printed quantum dots. The transfer printing process of the present disclosure avoids a situation that photoresist polymers in the inkjet printing technology are doped into a quantum dot solution. That is, the transfer printing process prevents the photoresist technology in a current manufacturing technology from having a greater impact on light efficiency and reliability of the quantum dots. In addition, after the red light and the green light pass through the quantum dot blocks and corresponding color resist blocks, pure red light and pure green light are emitted. After blue light is refracted by the high refractive index scattering particles, pure blue light is also emitted. This avoids a difference in viewing angles and color gamuts of R, G, and B color lights, thereby improving quality of light emitted by the quantum dot color filter substrate.

Please refer to FIG. 11, which is a schematic structural diagram of a fifth type of quantum dot color filter substrate 100 according to an embodiment of the present disclosure. A surface of the quantum dot color filter substrate 100 is provided with a barrier layer 130. The barrier layer 130 is made of silicon oxide, silicon nitride, or a combination thereof, and is configured to prevent water and oxygen from invading the quantum dot layer and the color resist layer. The other structure is similar to that of FIG. 10, and is not described in detail herein.

Please refer to FIG. 12, which is a schematic structural diagram of a sixth type of quantum dot color filter substrate 100 according to an embodiment of the present disclosure. Parts of the barrier layer 130 and parts of the quantum dot layer 120 corresponding to the R and G color resist blocks are provided with a metal layer 140. The metal layer 140 comprises silver. A nano silver (Ag) layer is configured as a surface plasmon resonance layer to improve a brightness of light. In addition, the metal layer 140 is not disposed on the B color resist blocks 113, thereby increasing a transmittance of the B color resist blocks 113. The other structure is similar to that of FIG. 10, and is not described in detail herein.

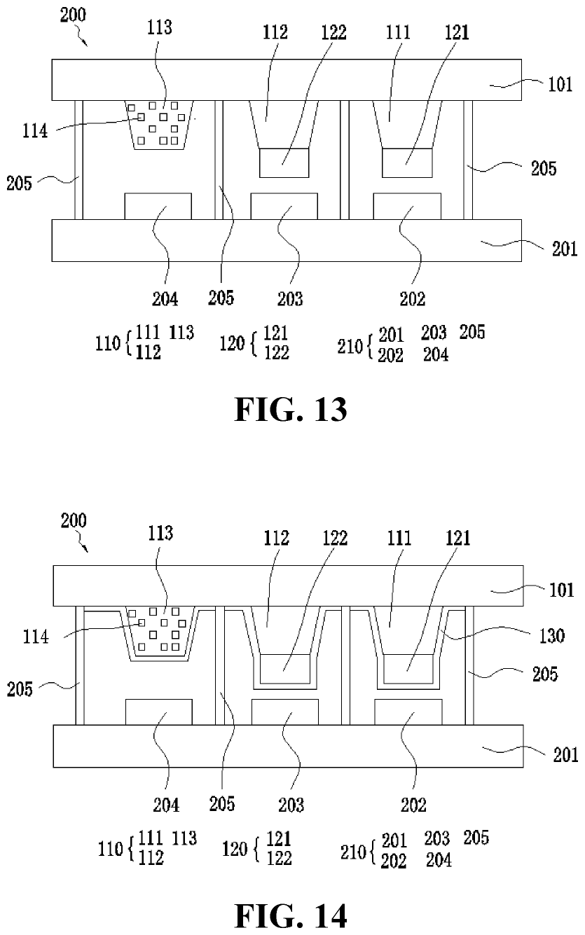

According to the above three types of quantum dot color filter substrates in FIG. 10 to FIG. 12, the present disclosure correspondingly provides three types of display devices. Please refer to FIG. 13, which is a schematic structural diagram of a display device according to an embodiment of the present disclosure. The display device 200 comprises a quantum dot color filter substrate as shown in FIG. 10 and a micro-LED backlight 210. The quantum dot color filter substrate is disposed on a light-emitting side of the micro-LED backlight 210. The micro-LED backlight 210 comprises a driving circuit board 201; a plurality of miniature red light-emitting devices 202, miniature green light-emitting devices 203, and miniature blue light-emitting devices 204 disposed on the driving circuit board; and a plurality of isolation walls 205 disposed between every two adjacent miniature light-emitting devices. The miniature red light-emitting devices 202, the miniature green light-emitting devices 203, and the miniature blue light-emitting devices 204 are disposed in alignment with the R color resister blocks 111, the G color resister blocks 112, and the B color resister blocks 113, respectively. A structure of the quantum dot color filter substrate is same as that of FIG. 10, which is not described in detail herein.

Please refer to FIG. 14, which is a schematic structural diagram of a second type of a display device according to an embodiment of the present disclosure. The display device 200 comprises a quantum dot color filter substrate as shown in FIG. 11 and a micro-LED backlight 210. The micro-LED backlight 210 is similar to that in FIG. 13, and a structure of the quantum dot color filter substrate is same as that of FIG. 11, and their specific structures are not described in detail herein.

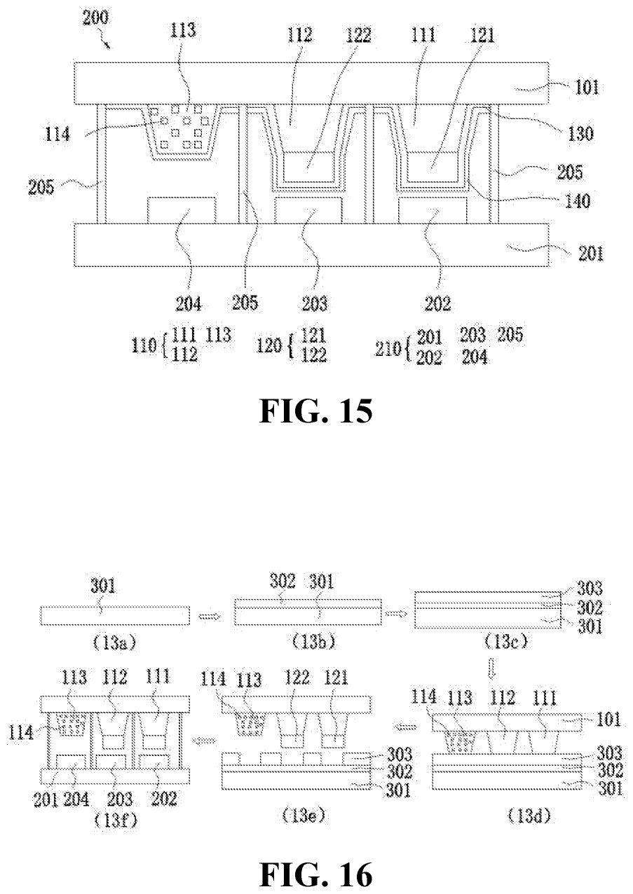

Please refer to FIG. 15, which is a schematic structural diagram of a third type of a display device according to an embodiment of the present disclosure. The display device 200 comprises a quantum dot color filter substrate as shown in FIG. 12 and a micro-LED backlight 210. The micro-LED backlight 210 is similar to that in FIG. 12, and a structure of the quantum dot color filter substrate is same as that of FIG. 12, and their specific structures are not described in detail herein.

According to the above display devices in FIG. 13 to FIG. 15, the present disclosure further provides a method for manufacturing a display device. The method comprises the following steps.

Step S10: providing a base substrate, forming a plurality of red (R) color resist blocks, green (G) color resist blocks, and blue (B) color resist blocks each having a structure with a wide top surface and a narrow bottom surface on the base substrate, and doping the B color resist blocks with a plurality of high refractive index scattering particles.

Step S20: providing a silicon substrate, forming a quantum dot layer on the silicon substrate, transferring parts of the quantum dot layer in contact with the R color resist blocks and the G color resist blocks to surfaces of the R color resist blocks and the G color resist blocks, and peeling off the silicon substrate to complete manufacture of a quantum dot color filter substrate.

Step S30: disposing the quantum dot color filter substrate in alignment with a corresponding micro-LED backlight to obtain the R/G/B display device.

Preferably, the step S10 specifically comprises: adding one or more crystalline materials selected from a group consisting of titanium dioxide, zirconium oxide, barium titanate, and titanium dioxide to the B color resist blocks. A mass fraction of the crystalline materials in the B color resist blocks is 0.5% to 8%. The crystalline materials have a size of 50 nm to 2000 nm. The step S10 further comprises: performing hydrophilic treatment on surfaces of the B color resist blocks, so that in the subsequent step S20, the quantum dot layer is selectively transfer printed to the R color resist blocks and the G color resist blocks, but not to the B color resist blocks.

Preferably, the step S20 further comprises: forming a barrier layer on a periphery of the quantum dot color filter substrate. The barrier layer is made of silicon oxide, silicon nitride, or a combination thereof. The barrier layer has a thickness of 1 nm to 50 nm. The step S20 further comprises: forming a metal layer on parts of the barrier layer corresponding to the R color resist blocks and the G color resist blocks. The metal layer is made of nano silver, a composite material of nano silver and silicon dioxide, a composite material of nano silver and titanium dioxide, or any combination thereof. The metal layer has a thickness of 1 nm to 50 nm.

Please refer to FIG. 16, which is a schematic flowchart of a method for manufacturing a display device according to an embodiment of the present disclosure. As shown in (13a) to (13c) in FIG. 16, a S1 substrate 301 is provided. After a surface of the S1 substrate 301 is cleaned, ODTS is coated on the surface of the S1 substrate to form an ODETS layer 302. ODTS is octadecyl trichlorosilane and its derivatives. A plurality of red and green quantum dots dispersed in a n-hexane solution are spin-coated on the ODTS layer 302 to form a quantum dot layer 303 with a thickness of 5 um to 20 um.

As shown in (13d) and (13e) in FIG. 16, a flexible photoresist (such as poly(dimethylsiloxane), PDMS) substrate 101 is patterned by a yellow light process to form a R/G/B photoresist layer. The photoresist layer is in contact with the quantum dot layer 303. Parts of the quantum dot layer 303 in contact with the R and G color resist blocks are transferred to surfaces of the R and G color resist blocks, heated at 50 to 100° C. for 10 min to 60 min, and then cooled to room temperature. The PDMS substrate 101 is quickly peeled from the S1 substrate 301 to complete manufacture of a quantum dot color filter substrate. Peeling forces of the following three layers: the ODETS layer 302<the PR-PDMS substrate<the quantum dot layer 303. In these steps, a photoresist color resist technology has high precision and meets high-resolution requirements. A transfer printing process of quantum dots is not affected by the yellow light process and can maintain high efficiency. Photoresists prevent ambient light from exciting quantum dots to emit light, thereby improving contrast. The other layers may be treated after the transfer printing process to improve reliability and light conversion efficiency. The B color resist blocks are treated with hydrophilic treatment, so the quantum dots will not be transferred to them, which improves a transmittance and a color gamut of blue light. These steps can be applied to flexible display products. Before the R color resist blocks 111 and the G color resist blocks 112 are transfer printed with quantum dot blocks, the B color resist blocks 113 are doped with a plurality of high refractive index scattering particles 114.

As shown in (13f) in FIG. 16, the quantum dot color filter substrate is disposed in alignment with a corresponding micro-LED backlight to obtain the R/G/B display device of FIG. 6. The micro-LED backlight comprises a driving circuit board 201; a plurality of miniature red light-emitting devices 202, miniature green light-emitting devices 203, and miniature blue light-emitting devices 204 disposed on the driving circuit board; and a plurality of isolation walls disposed between every two adjacent miniature light-emitting devices.

Please note that structures of the other display devices are similar to that of FIG. 13. The barrier layer and the metal layer are generally formed by evaporation or coating. After the transfer printing process is completed, a silicon oxide layer or a silicon nitride layer with a thickness of 1 nm to 50 nm is vapor-deposited on a surface of the quantum dot layer at a low temperature to form the barrier layer to block water and oxygen. An Ag metal layer with a thickness of 1-50 nm is sputtered on an outside at room temperature to form the metal layer. In order to improve a light conversion efficiency of the quantum dots, after the metal layer is sputtered, parts of the metal layer on surfaces of the B color resist blocks may be selectively etched to increase a transmittance of the B color resist blocks.

In addition, 0.3-8 wt % titanium dioxide, zirconium oxide, barium titanate, or titanium dioxide, or other high refractive index scattering particles with a size of 50 nm to 2000 nm are added to the B color resist blocks. The hydrophilic treatment is performed on surfaces of the blue photoresist, and then a transfer printing process of the quantum dot layer is performed. This can selectively transfer print the quantum dot layer to the surfaces of the R color resist blocks and the G color resist blocks, thereby increasing transmittance of the blue photoresist, diffusing blue light, and reducing a difference in viewing angles of brightness of lights emitted from the R color resist blocks, the G color resist blocks, and the B color resist blocks. The rest of the method will not be repeated herein.

In FIG. 10 to FIG. 16, the quantum dot blocks are transfer printed to the R color resist blocks 111 and the G color resist blocks 112, and the quantum dot blocks are not disposed under the B color resist blocks 113. The B color resist blocks 113 are added with the high refractive index scattering particles. After the red light and the green light pass through the quantum dot blocks and corresponding color resist blocks, pure red light and pure green light are emitted. After blue light is refracted by the high refractive index scattering particles, pure blue light is also emitted. This avoids a difference in viewing angles and color gamuts of R, G, and B color lights, thereby improving quality of light emitted by the quantum dot color filter substrate.

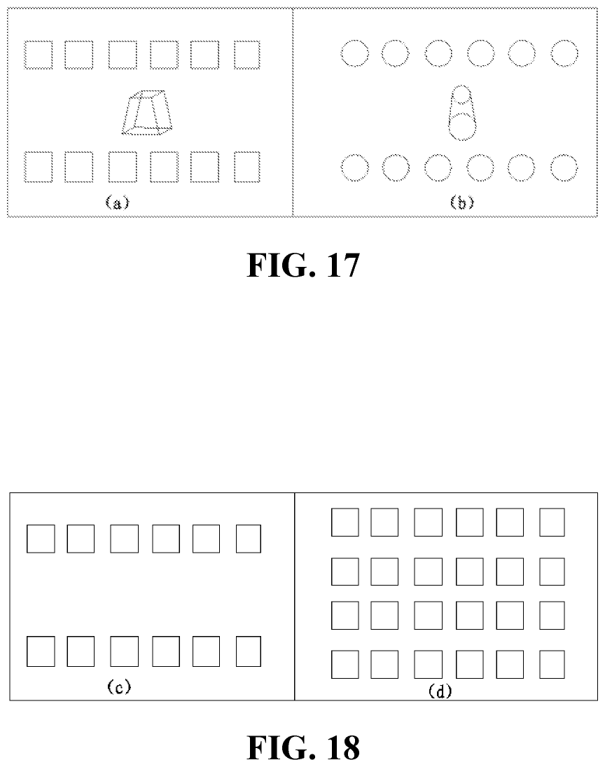

Please refer to FIG. 17, which is a schematic structural diagram of R color resister blocks, G color resister blocks, and B color resister blocks according to an embodiment of the present disclosure. In (a) of FIG. 17, the R color resist blocks, the G color resist blocks, and the B color resist blocks are square bosses, which are arranged in two rows in an order of the R color resist blocks, G color resist blocks, and B color resist blocks. In (b) of FIG. 17, the R color resist blocks, the G color resist blocks, and the B color resist blocks are circular bosses, which are arranged in two rows in an order of the R color resist blocks, G color resist blocks, and B color resist blocks.

FIG. 18 to FIG. 20 are schematic structural diagrams of quantum dot blocks according to an embodiment of the present disclosure. In FIG. 18 to FIG. 20, the quantum dot blocks are transfer printed to R color resist blocks, G color resist blocks, and B color resist blocks at a same time, or are transfer printed to the R color resist blocks and the G color resist blocks at the same time. They are different according to specific structures of quantum dot color filter substrates, but their processes and methods of transfer printing are similar.

As shown in FIG. 18, the quantum dot blocks are square bosses. In (c) in FIG. 18, upper and lower rows are transfer printed. Then, in (d) in FIG. 18, their next rows are transfer printed. A whole transfer printed image is a square array structure. Two rows of the quantum dot blocks are transfer printed every time.

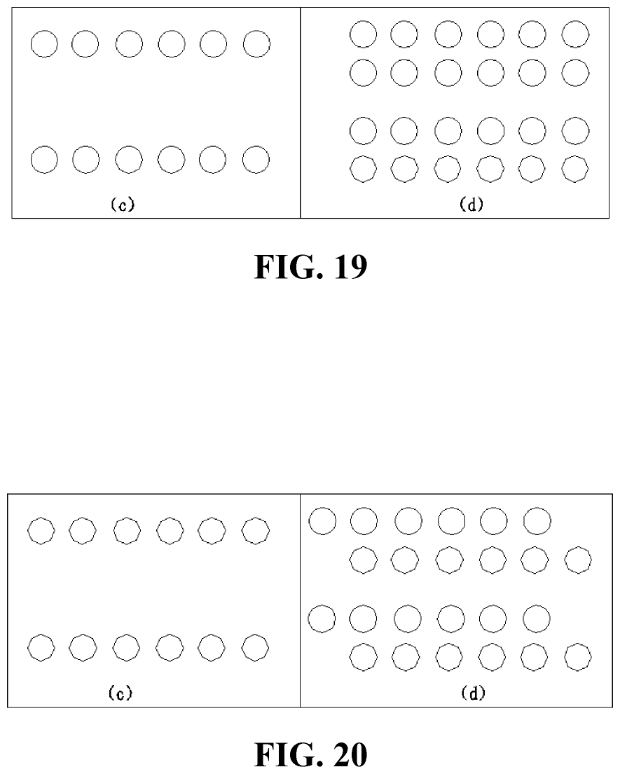

As shown in FIG. 19 and FIG. 20, the quantum dot blocks are circular bosses. In (c) in FIG. 19, upper and lower rows are transfer printed in a first transfer printing process. Then, in (d) in FIG. 19, their next rows are transfer printed in a second transfer printing process. A whole transfer printed image is a array structure. In (c) in FIG. 20, upper and lower rows are transfer printed in a first transfer printing process. Then, in (d) in FIG. 20, their next rows are transfer printed in a second transfer printing process. A whole transfer printed image is a parallelogram array structure. In order to further improve a utilization rate of transfer printing, if a circular cross-sectional diameter of the quantum dot blocks is D, the positions of the second transfer printing process are horizontally moved by D/2 and vertically moved by 0.9D compared with positions of the first transfer printing process.

The present invention has been described in the above preferred embodiments, but the above preferred embodiments are not intended to limit the present invention. Those skilled in the art may make various changes and modifications without departing from the scope of the present invention. The scope of the present invention is determined by claims.

1. A method for manufacturing a quantum dot color filter substrate, comprising:
step S10: forming a color resist layer under a base substrate, wherein the color resist layer comprises a plurality of red (R) color resist blocks, green (G) color resist blocks, and blue (B) color resist blocks arranged in an array, each of the R color resister blocks, the G color resister blocks, and the B color resister blocks has a structure with a wide top surface and a narrow bottom surface, and the wide top surface contacts a bottom surface of the base substrate;
step S20: forming a quantum dot layer on a silicon substrate, wherein the quantum dot layer is a mixed layer comprising a plurality of red quantum dots and green quantum dots; and
step S30: heating the quantum dot layer and the color resist layer, contacting them, keeping them warm for a preset time, cooling them to room temperature, and peeling off the silicon substrate to transfer at least parts of the quantum dot layer in contact with the R color resist blocks and the G color resist blocks to surfaces of the R color resist blocks and the G color resist blocks, so that a plurality of quantum dot blocks are formed on the narrow bottom surfaces of the R color resist blocks and the G color resist blocks.

2. The method for manufacturing the quantum dot color filter substrate according to claim 1, wherein the step S30 further comprises:
transferring parts of the quantum dot layer in contact with the B color resist blocks to surfaces of the B color resist blocks.

3. The method for manufacturing the quantum dot color filter substrate according to claim 1, wherein the step S10 further comprises:
adding a plurality of high refractive index scattering particles into the B color resist blocks, wherein the high refractive index scattering particles are one or more crystalline materials selected from a group consisting of titanium dioxide, zirconium oxide, and barium titanate, and a mass fraction of the crystalline materials in the B color resist blocks is 0.3% to 8%; and
performing hydrophilic treatment on the surfaces of the B color resist blocks.

4. The method for manufacturing the quantum dot color filter substrate according to claim 3, wherein the step S30 further comprises:
forming a barrier layer on a periphery of each of the quantum dot blocks, wherein the barrier layer is made of silicon oxide, silicon nitride, or a combination thereof, and the barrier layer has a thickness of 1 nm to 50 nm.

5. The method for manufacturing the quantum dot color filter substrate according to claim 4, wherein the step S30 further comprises:
forming a metal layer on parts of the barrier layer corresponding to the R color resist blocks and the G color resist blocks, wherein the metal layer is made of nano silver, a composite material of nano silver and silicon dioxide, a composite material of nano silver and titanium dioxide, or any combination thereof, and the metal layer has a thickness of 1 nm to 50 nm.

6. A quantum dot color filter substrate, comprising:
a base substrate;
a color resist layer disposed under the base substrate and comprising a plurality of red (R) color resist blocks, green (G) color resist blocks, and blue (B) color resist blocks arranged in an array, wherein each of the R color resister blocks, the G color resister blocks, and the B color resister blocks has a structure with a wide top surface and a narrow bottom surface, and the wide top surface contacts a bottom surface of the base substrate; and
a quantum dot layer comprising a plurality of quantum dot blocks arranged in an array, wherein the quantum dot blocks are made of a mixed layer comprising a plurality of red quantum dots and green quantum dots, and the quantum dot blocks are disposed at least under the narrow bottom surfaces of the R color resist blocks and the G color resist blocks.

7. The quantum dot color filter substrate according to claim 6, wherein a cross-sectional shape of the structure with the wide top surface and the narrow bottom surface is an inverted isosceles trapezoid.

8. The quantum dot color filter substrate according to claim 6, wherein the quantum dot blocks are disposed under and in alignment with the B color resist blocks.

9. The quantum dot color filter substrate according to claim 8, further comprising:
a barrier layer disposed on a periphery of each of the quantum dot blocks and made of silicon oxide, silicon nitride, or a combination thereof.

10. The quantum dot color filter substrate according to claim 9, further comprising:
a metal layer disposed on parts of the barrier layer corresponding to the R color resist blocks and the G color resist blocks and comprising silver.

11. The quantum dot color filter substrate according to claim 6, wherein the quantum dot blocks are not disposed under the B color resist blocks, and the B color resist blocks are added with a plurality of high refractive index scattering particles.

12. The quantum dot color filter substrate according to claim 11, further comprising:
a barrier layer disposed on a periphery of each of the quantum dot blocks and made of silicon oxide, silicon nitride, or a combination thereof.

13. The quantum dot color filter substrate according to claim 12, further comprising:
a metal layer disposed on parts of the barrier layer corresponding to the R color resist blocks and the G color resist blocks and comprising silver.

14. The quantum dot color filter substrate according to claim 11, wherein the high refractive index scattering particles are made of one or more of titanium dioxide, zirconium oxide, and barium titanate, and a mass fraction of the high refractive index scattering particles in the B color resist blocks is 0.3% to 8%.

15. The quantum dot color filter substrate according to claim 6, wherein the green quantum dots are made of one or more of ZnCdSe₂, InP, and Cd₂SSe, and the red quantum dots are made of one or more of CdSe, Cd₂SeTe, and InAs.

16. The quantum dot color filter substrate according to claim 7, wherein an inclination angle between two waists of the inverted isosceles trapezoid and a horizontal line is 15° to 45°.

17. A display device, comprising:
a micro-light emitting diode (micro-LED) backlight; and
the quantum dot color filter substrate according to claim 6 disposed on a light-emitting side of the micro-LED backlight.

18. The display device according to claim 17, wherein the micro-LED backlight comprises:
a driving circuit board;
a plurality of miniature red light-emitting devices, miniature green light-emitting devices, and miniature blue light-emitting devices disposed on the driving circuit board; and
a plurality of isolation walls disposed between every adjacent two of the miniature red light-emitting devices, the miniature green light-emitting devices, and the miniature blue light-emitting devices.

19. The display device according to claim 18, wherein
the quantum dot color filter substrate comprises the R color resister blocks, the G color resister blocks, and the B color resister blocks arranged in the array; and
the miniature red light-emitting devices, the miniature green light-emitting devices, and the miniature blue light-emitting devices are disposed in alignment with the R color resister blocks, the G color resister blocks, and the B color resister blocks, respectively.

20. The display device according to claim 19, wherein
the quantum dot blocks are disposed under and in alignment with the B color resist blocks; or
the quantum dot blocks are not disposed under the B color resist blocks, the B color resist blocks are added with a plurality of high refractive index scattering particles, the high refractive index scattering particles are made of one or more of titanium dioxide, zirconium oxide, and barium titanate, and a mass fraction of the high refractive index scattering particles in the B color resist blocks is 0.3% to 8%.
